(19) United States
(12) Patent Application Publication
(10) Pub. No.: US 2002/0074637 A1
(43) Pub. Date: Jun. 20, 2002

(54) Stacked flip chip assemblies

(75) Inventor: Jonathan McFarland, Tempe, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 09/741,370

(22) Filed: Dec. 19, 2000

(51) Int. Cl. H01L 21/44; H01L 21/48; H01L 29/40; H01L 23/34; H01L 23/48; H01L 23/52; H01L 21/50

(52) U.S. Cl. 257/686; 257/723; 257/737; 257/777; 257/778; 438/108; 438/109

(57) ABSTRACT

A stacked flip chip assembly that substantially enhances integrated circuit density and reliability in a multi chip module by electrically coupling a first die to a conductive surface of a substrate through a flip chip attachment. The assembly further includes electrically coupling a second die to the first die through the flip chip attachment such that the second die is disposed on the first die and across from the substrate. The assembly also includes a third die electrically coupled to the second die through the flip chip attachment such that the third die is disposed on the second die and across from the second die and the substrate. Further, the second and third dies are electrically coupled to the substrate through the first and second dies by having conductive redistribution traces on sides of the first and second dies to route electrical signals from the second and third dies to the substrate and vice versa.

### TECHNICAL FIELD

This invention relates generally to semiconductor packaging technology, and more particularly to increasing semiconductor device density (within a package of given size) and reliability.

### BACKGROUND

The terms “chip,” “die,” “semiconductor die,” and “integrated circuit die” are used interchangeably throughout the document. Also, the terms “semiconductor device” and “integrated circuit device” are used interchangeably throughout the document. Further, the terms “layers” and “traces” are also used interchangeably throughout the document.

The trend in microelectronic packaging is going towards smaller and lighter packages. As the microelectronic packages become physically more compact and operate at ever-faster speeds, the amount of “real-estate” available on circuit boards and other component-supporting substrates becomes ever smaller. Various die packaging schemes have evolved to promote greater component density. Such as integrated circuits packaged in plastic or ceramic packages with extending metal leads for soldering on to a printed circuit board or for insertion into a socket. In most cases, a single package will only contain a single integrated circuit, although multiple chips are more commonly being manufactured within a single package. The use of such multiple chips in packages results in a low circuit density as the single integrated circuit ceramic or a plastic package consumes relatively large areas of real-estate on the circuit boards, particularly if a socket is used.

Multi chip module technology has been developed to suit applications where it is necessary to reduce the size of the assembly or where speed or electrical noise considerations require shorter connecting leads. A typical multi chip module package combines a number of individual or unpackaged integrated circuits and directly attaches them to a mounting surface, for example ceramic substrate, printed circuit board or other substrate. Integrated circuits within multi chip module assemblies can be electrically connected using various bonding techniques such as soldering, wire bonding, and flip-chip technologies. Many multi chip module assemblies are generally constructed in a two dimensional array to reduce the associated surface area required if the individual packaged devices were mounted on circuit boards.

It has, however, been recognized that it may be desirable in certain applications to enhance circuit density by vertically stacking dies in two or more layers. In order to achieve the stacked dies, one must be able to route the signals from the dies down to the substrate. The existing vertical stacking packaging techniques interconnect vertically stacked dies using wire bonding (flip chipping the first die connected either to a substrate and then wire bonding the additional die on top of the first die for a hybrid flip chip wire bond assembly) or by using through silicon vias in the die. Through silicon vias allow several dies to be stacked directly on top of each other and interconnect the stacked circuit layers (through silicon vias are metal filled vias designed to contact bumps on an adjacent die). Where as the flip chip technology allows the electrical and mechanical connection of a chip to a substrate by inverting and bonding the chip face down to the substrate interconnection pattern. The interconnection between the chip and the substrate in the flip chip connection is accomplished by having raised metallic bonding bumps on each of the chip mounting pads corresponding to the conductive land areas on the substrate and joining the conductive pads to the conductive land areas on the substrate by using controlled reflow solder techniques or conductive epoxy techniques.

The packaging industry has been moving away from wire-bonding packages in high-performance applications for a while now, because flip chip packages generally have superior electrical and mechanical performance characteristics over the wire bond packages. Also, bonding wires of conventionally assembled chip-on-chip packages have an associated conductance and capacitance that may be significant and may result in a reduction of reliability in certain high-speed applications. That is, wire bond interconnections provide limited electrical performance compared to several other interconnect types, such as flip chip interconnects. Additionally, bonded wires are associated with a decreased overall reliability when used in the chip-on-chip packages. During the encapsulation process, the bonding wires may be displaced and can result in an increased number of shorts within the chip-on-chip package. In general the assembly process for conventional chip-on-chip packages including wire bonding is complex and expensive when compared with the assembly process of flip chip packages. By way of example, the delicate bonding wires of conventional chip-on-chip packages require encapsulation material to protect them from stresses, and thus, the overall size of the conventional chip-on-chip packages can increase based on the amount of encapsulation material used. Additionally, conventional chip-on-chip packages using wire bond processes have a limited product throughput due to a further dependency on the throughput of the underlying wire bond and mold processes.

The vertical interconnection between one stacked die to another adjacent stacked die can also be achieved by using the through silicon vias to contact bumps on the adjacent dies. Although this is an efficient connection method between the adjacent dies, this method is not feasible to be employed when using integrated circuits made from different manufacturers. Further, the device is mounted in a housing which significantly reduces the silicon density of the device due to the consumption of certain amount of silicon area for the through silicon vias.

Therefore, there is a need for an improved chip-on-chip packaging technique and assembly for increasing integrated circuit density and reliability. Additionally, there also is a need for a simplified commercially available, widely practiced semiconductor device fabrication technique for making such chip-on-chip assemblies and mounting such assemblies onto a substrate to enhance the product throughput in the chip-on-chip packaging processes.

### BRIEF DESCRIPTION OF THE DRAWINGS

FIG. 1 shows a front elevational view of one embodiment of a stacked flip chip assembly fabricated according to the teachings of the present invention.

FIG. 2 shows a perspective view of one embodiment of forming conductive distribution and conductive redistribution layers on a die that facilitates in electrically connecting the stacked flip chip assembly shown in FIG. 1.

FIG. 3 shows a top view of one embodiment of forming conductive pads and conductive distribution layers on a backside of a die that facilitates in electrically connecting the stacked flip chip assembly shown in FIG. 1.

FIG. 4 is a perspective view of one embodiment of forming conductive redistribution traces on sides of the dies according to the teachings of the present invention.

FIG. 5 is a perspective view of another embodiment of forming conductive redistribution traces on sides of the dies according to the teachings of the present invention.

FIG. 6 is a flow diagram of one embodiment of the present invention.

### DETAILED DESCRIPTION

In the following detailed description of the embodiments, reference is made to the accompanying drawings that show, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

The present invention provides an improved stacked chip assembly that substantially increases integrated circuit density and reliability in a multi chip module. By replacing the currently used wire bonding technique with flip chip technology to electrically couple first, second and third dies to a substrate through flip chip attachment and redistribution traces on sides of the first and second dies to rout the electrical signals from the second and third dies to the substrate and vice versa.

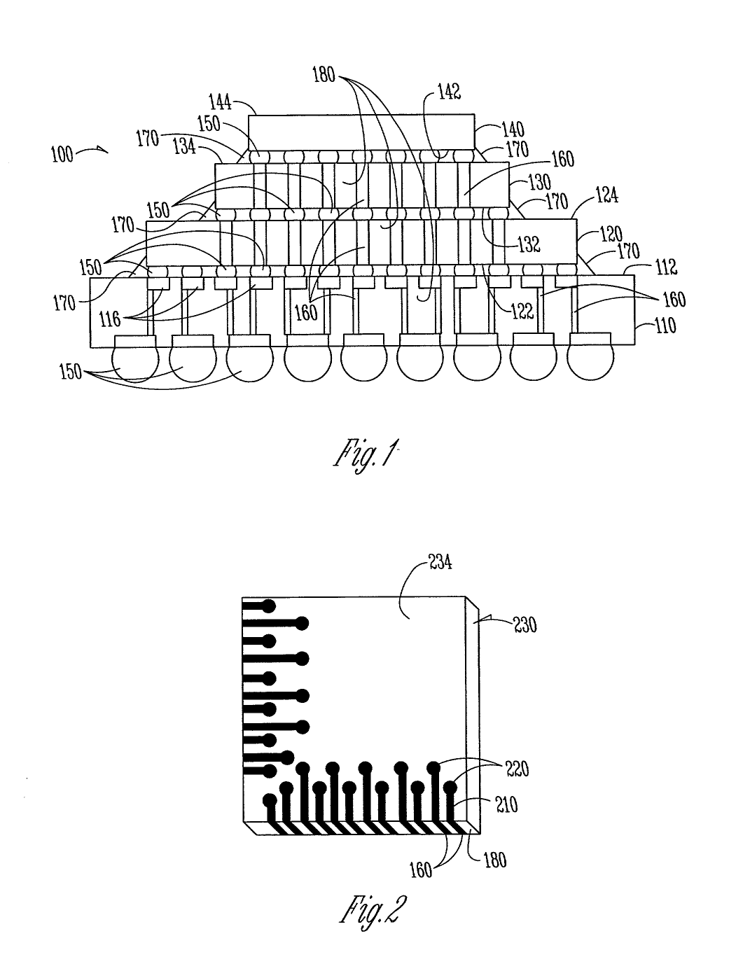

FIG. 1 shows an example embodiment of a stacked flip chip assembly 100. The stacked flip chip assembly 100 includes a substrate 110, and first, second, and third dies 120, 130, and 140. The first, second, and third dies 120, 130, and 130, can be formed from semiconductor materials such as silicon, gallium arsenide, silicon on insulator, or any other suitable substrates that can be used to support integrated circuit layers. Also shown in FIG. 1 are conductive redistribution traces 160 on the first and second dies 120 and 130 electrically connecting front and backsides of the first and second dies 120 and 130, and an under fill material 170 used to mechanically retain the stacked flip chip assembly in place.

In the example embodiment shown in FIG. 1, a frontside 122 of the first die 120 is electrically connected through flip chip attachment to a conductive surface 112 of the substrate 110. In some embodiments, the substrate 110 is a printed circuit board. The conductive surface 112 of the substrate includes a plurality of conductive layers. In the embodiment shown in FIG. 1, the frontside 122 of the first die 120 has a plurality of conductive bumps 150. Also, shown in FIG. 1 is a frontside 132 of the second die 130 connected through flip chip attachment to a backside 124 of the first die 120. Further FIG. 1, also shows a frontside 142 of an optional third die 140 connected through flip chip attachment to a backside 134 of the second die 130. It can be envisioned by those skilled in the art that the stacked flip chip assembly 100 shown in FIG. 1 is not limited to connecting through flip chip attachment to only three dies 120, 130, and 140, any number of dies can be stacked and connected using such stacked flip chip arrangement, as long as the design of the packaged assembly permits. The first, second, and third dies 120, 130, and 140 can be integrated circuit devices such as microprocessors, logic devices, memories, or any other application specific integrated circuits. The terms “frontside,” “backside,” and “sides” of a die, as used herein, refer to the sides of a semiconductor chip or a die which carries integrated circuitry. Also the term “backside” as used herein, refers to a side of the semiconductor chip or die that is disposed across from the frontside.

As shown in FIG. 1, the substrate 110, and the first, second, and third dies 120, 130, and 140 are all electrically connected to each other through a flip chip attachment. This is accomplished by having conductive layers on the frontsides 122, 132, and 142 of the three dies 120, 130, and 140, and also having conductive layers on the backsides 124, and 134 of the first and second dies 120 and 130, and further having conductive redistribution traces 160 on at least one side 180 of each of the first and second dies 120, and 130.

FIG. 1 also shows a conductive surface 112 on the substrate 110 having a plurality of conductive pads 116. Also, shown are the frontsides 122, 132, and 142 of the first, second, and third dies 120, 130, and 140 having a plurality of conductive bumps 150. As shown in FIG. 1, the stacked flip chip assembly 100 includes a plurality of pads on the backsides of the first and second dies 120 and 130 to electrically connect and match the plurality of bumps 150 on the frontsides 132 and 142 of the second and third dies 130 and 140, respectively. The plurality of conductive pads 116 on the conductive surface 112 of the substrate 110 are also positioned to match the plurality of conductive bumps 150 on the frontside 122 of the first die 120. The plurality of conductive bumps 150 can be solder balls, solder bumps, solder protrusions, controlled collapse chip connects (also known in the art as C4 solder connections) or any other conductive protrusions that facilitate in providing an electrical connection with the plurality of conductive pads 116. As shown in FIG. 1, the substrate 110 also has a plurality of conductive bumps 150 on a side opposite from the conductive surface 112 for electrically coupling the stacked flip chip assembly 100 to a mother board assembly or other similar printed circuit board assembly. It can be envisioned that the front and backsides 122, 132, 142, 124, 134, 144 of the first, second, and third dies 120, 130, and 140 can have both the plurality of bumps 150 and the plurality of conductive pads 116 to satisfy a specific electrical connection needs in the stacked flip chip assembly 100. The plurality of pads 116 on the substrate 110 and the plurality of bumps 150 on the front side of the first die are sufficient to electrically connect the first, second, and third dies 120, 130, and 140 to the substrate 110. The plurality of conductive pads 116 can be input/output pads, or power and ground plane pads. The design of the stacked flip chip assembly 100 can be optimized to reduce the number of redistribution traces 160 required on the sides 180 of the dies to rout the electrical signals from the second and third dies 130 and 140 by disposing the dies (for example memory chips) requiring a least number of input/output pads to be placed on the top of the stacked assembly 100. Dies requiring the highest number of input/output pads are preferably placed at the bottom of the stacked assembly 100.

The first, and second dies 120 and 130 can have integrated circuit layers on both the front and backsides. As shown in FIG. 1, the front sides 122, 132, and 142 of the first, second, and third dies 120, 130, and 140 have integrated circuit layers. The back sides 124 and 134 of the first and second dies 120 and 130 also have integrated circuit layers. Also, shown in FIG. 1 are the conductive redistribution traces 160 on the sides 180 of the first and second dies 120 and 130. The redistribution traces 160 electrically connect the integrated circuitry on the front and backsides 122, 132, 142, 124, and 134 of the first, second, and third dies 120, 130, and 140, respectively. The addition of redistribution traces 160 to the first and second dies 120 and 130 of the stacked flip chip assembly 100 shown in FIG. 1 makes it possible for the electrical signals to be routed from the first, second, and third dies 120, 130, and 140 to the conductive surface 112 of the substrate 110 and vice versa.

The redistribution traces 160 can be formed using electrically conductive materials such as copper with a material that promotes adhesion to the substrate of the dies. The redistribution traces 160 on the sides 180 of the first, second, and third dies 120, 130, and 140 can be formed using commercially available fabrication techniques such as masking, sputtering, photo-patterning, laser direct imaging, or any other techniques suitable for forming side traces on the dies.

The first, second, and third dies 120, 130, and 140 including the integrated circuit layers on the front and backsides 122, 132, 142, 124, and 134 can be formed using substrates such as silicon, gallium arsenide, silicon on insulator, or any other suitable substrate that can be used to support the integrated circuit layers. The first, second, and third dies 120, 130, and 140 can be integrated circuit devices. The integrated circuit devices can include microprocessors, logic devices, memories, and any other application specific integrated circuit devices. The underfill material 170 can be any encapsulant or an overmold that assists in mechanically retaining the stacked flip chip assembly in place.

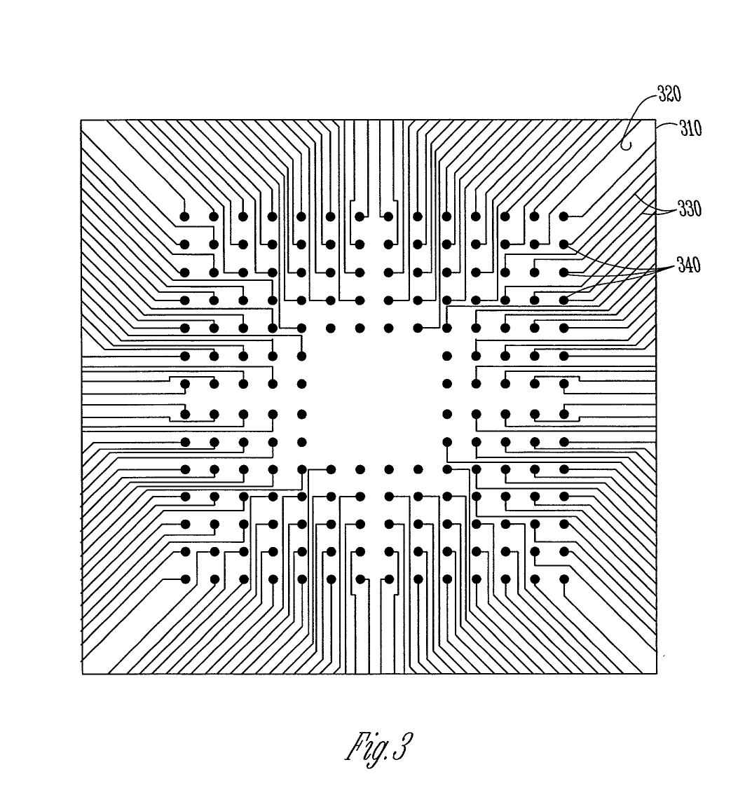

FIG. 2 shows an example embodiment of forming conductive layers 210 on a backside 234 of a die 230. Also, shown in FIG. 2 are forming the plurality of conductive pads 220 at the beginning of each of the plurality of conductive layers 210. The plurality of conductive pads 220 are disposed on the backside 234 of the die 230 in such a way as to match a plurality of the conductive bumps disposed on a front side of another die to be electrically attached to the backside 234 of the die 230 through a flip chip attachment.

It can be envisioned that the plurality of conductive pads 220 and the plurality of conductive layers 210 shown in FIG. 2, can be formed on the backsides 124 and 134 of the first and second dies 120 and 130 to electrically connect the first, second, and third dies 120, 130, and 140 of the stacked flip chip assembly 100 shown in FIG. 1, through flip chip attachment.

FIG. 2 also shows the forming of the conductive redistribution traces 160 around the sides 180 of the die 230. Also shown in FIG. 2 is the electrical connection of the redistribution traces 160 to the conductive layers on the backside 234 of the die 230. It can also be envisioned that the redistribution traces 160 shown in FIG. 2 can also be connected to the conductive layers on a frontside of the die 230 so that the electrical signals can be routed from the backside 234 to the frontside of the die 230 and vice versa. The redistribution traces 160 can be formed using electrically conductive materials such as copper with a material that promotes adhesion to the substrate of the dies. The redistribution traces 160 on the sides 180 of the die 230 can be formed using commercially available fabrication processes such as masking, sputtering, photo-patterning, laser direct imaging, or any other techniques suitable for forming side traces on the dies. It can also be envisioned that the redistribution traces 160 shown in FIG. 2 can be formed on at least one of the sides 180 of the first, second and third dies 120, 130, and 140 to electrically connect the conductive layers on the front and backsides 122, 132, 142, 124, and 134 of the first, second, and third dies 120, 130, and 140, respectively. In the example embodiment shown in FIG. 2 the redistribution traces 160 are on two sides 180 of the die 230. It can be envisioned that the redistribution traces can be formed one or more sides 180 of the die 230. The redistribution traces 160 shown in FIG. 2 facilitate in electrically connecting the first, second, and third dies 120, 130, and 140 and in routing the electrical signals from the first, second, and third dies to the conductive surface 112 of the substrate 110 and vice versa through the flip chip attachment shown in FIG. 1.

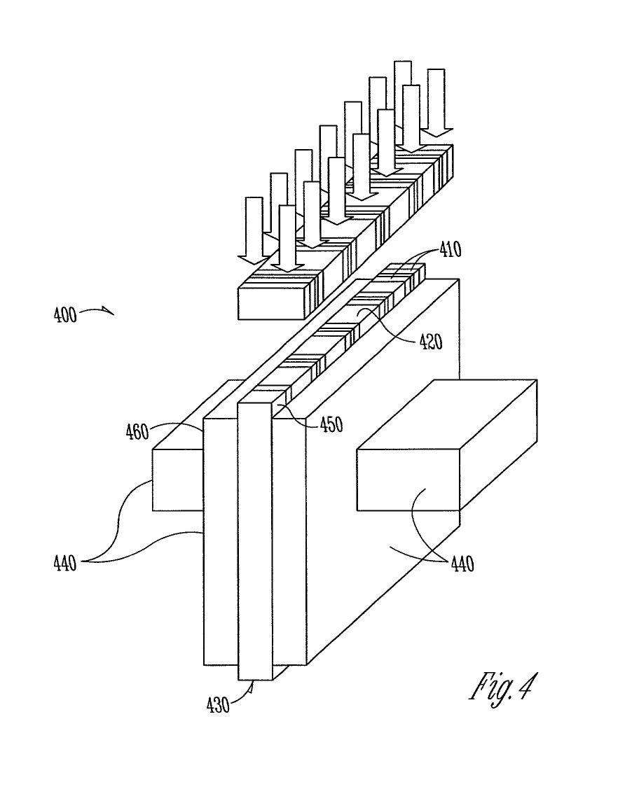

FIG. 3 shows another example embodiment of forming conductive layers 330 on a backside 320 of a die 310. Also, shown in FIG. 3 are forming plurality of conductive pads 340 at the beginning of each of plurality of conductive layers 330. The plurality of conductive pads 340 are disposed on the backside 320 of the die 310 such a way as to match a plurality of the conductive bumps disposed on a front side of another die to be electrically attached to the backside 320 of the die 310 through a flip chip attachment. It can be envisioned that the plurality of conductive pads 340 and the conductive layers 330 shown in FIG. 3 can also be formed on the backsides 124 and 134 of the first and second dies 120 and 130 to electrically connect the first, second, and third dies 120, 130, and 140 through flip chip attachment of the stacked flip chip assembly 100 shown in FIG. 1.

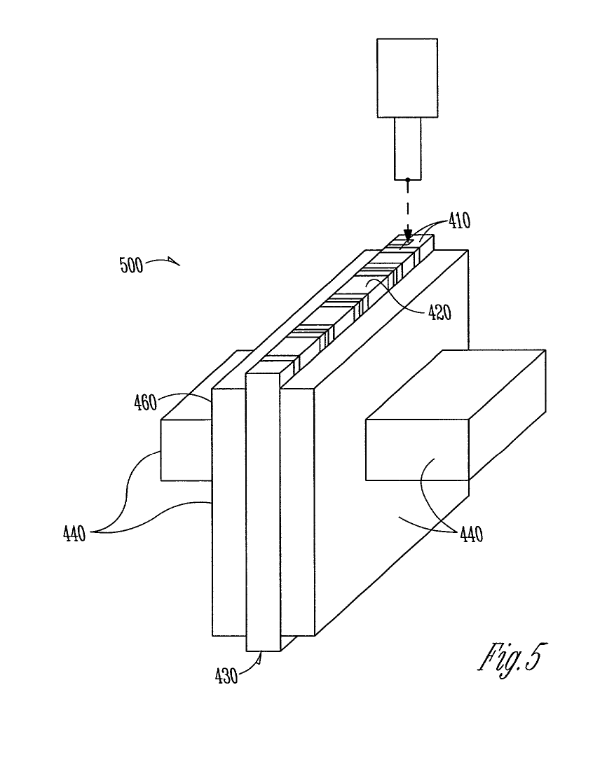

FIG. 4 shows an example embodiment 400 of a commercially available fabrication technique such as a photo-patterning technique that can be used to form conductive redistribution traces 410 on at least one side 420 of a die 430. Also shown in FIG. 4 is a specially designed clamping/masking device 440 that can be used to hold and mask the die 430 during the forming of the conductive redistribution traces 410 on at least one side 420 of the die 430. The clamping/masking device 440 facilitates in holding and masking the front and backsides 450 and 460 of the die 430 such that the formation of the redistribution traces 410 is confined only to the at least one side 420 of the die 430. It can be envisioned that photo-patterning technique shown in FIG. 4 to form the redistribution traces 410 can be used in forming the redistribution traces 160 on at least one of the sides 180 of the first, second, and third dies 120, 130 and 140 shown in FIG. 1.

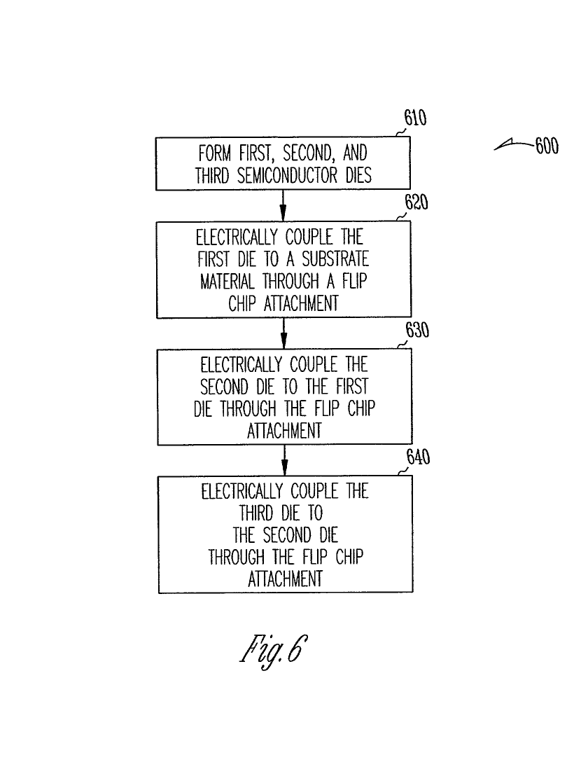

FIG. 5 shows an example embodiment of another commercially available fabrication technique such as a laser direct imaging technique 500 that can be used to form the conductive redistribution traces 410 on at least one side 420 of a die 430 using the specially designed clamping/masking device 440 that facilitates in holding and masking the die 430 during the forming of the conductive redistribution traces 410 on at least one side 420 of the die 430. It can also be envisioned that the photo-patterning technique shown in FIG. 4 to form the redistribution traces 410 can be used in forming the redistribution traces 160 on at least one of the sides 180 of the first, second, and third dies 120, 130 and 140 shown in FIG. 1.

FIG. 6 is a flow diagram illustrating a method 600 of packaging a stacked flip chip assembly that substantially increases integrated circuit density and reliability in a multi chip module. Method 600 as shown in FIG. 4, begins with action 610 of forming first, and second dies, and an optional third semiconductor die from a semiconductor wafer. The semiconductor wafer can be made from materials such as silicon, a gallium arsenide, a silicon on insulator, or any other such materials suitable for using as a substrate capable of supporting integrated circuit layers.

In some embodiments, the first, second, and third semiconductor dies are formed having front and backsides by cutting the semiconductor wafer such that the front and backsides are disposed across from each other. The next action includes forming patterned conductive distribution layers on the front and backsides of the first, second, and third dies. The next action includes adding a plurality of conductive bump interconnect materials and conductive pads to the front and backsides of the first, second, and third dies. The method further includes forming a plurality of conductive redistribution traces on at least one of the sides of the first and second dies to electrically connect the formed conductive distribution layers on the front and backsides of the first and second dies by masking the front and backsides such that only the at least one of the sides of the first and second dies are exposed to form the conductive redistribution traces.

In some embodiments, forming the patterned conductive distribution layers on the front and backsides of the first, second, and third dies further include depositing mechanically protective layers over the patterned conductive distribution layers. It also includes depositing diffusion layers over the deposited mechanically protective layers, and further depositing adhesion layers over the diffusion barrier layers. The method further includes depositing electrically conductive layers over the adhesion layers and patterning the electrically conductive layers, and further depositing protective layers over the patterned electrical layers. In addition, the method further includes patterning the plurality of conductive bump materials, and patterning protective layers over the conductive bump materials. The method further includes patterning diffusion layers over the protective layers.

In some embodiments, forming the conductive redistribution traces on at least one of the sides of the first, second, and third dies further includes holding at least one of the first, second, and third dies in place using a specially designed positioning device such that the front and back sides of the at least one of the first, second, and third dies are masked. The method further includes depositing and patterning a mechanically protective layer over at least one of the sides of the first, second, and third dies, and further depositing a diffusion barrier over the mechanically protective layer. In addition, the method also includes depositing an adhesive layer over the diffusion barrier and depositing electrically conductive layers connecting the patterned conductive traces on the front and backsides of the first, second, and third dies. The method further includes patterning the electrically conductive layers and depositing a protective layer over the patterned electrically conductive layers. Further, the method includes patterning a protective layer over the deposited protective layer, and patterning a diffusion layer over the protective layer.

The next action 620 in the method 600 includes electrically coupling the first die to a substrate through a flip chip attachment. In some embodiments, the frontside of the first die including the plurality of conductive bumps is electrically coupled to a conductive surface including a plurality of conductive traces and conductive pads on the substrate.

The next action 630 includes electrically coupling the second die to the substrate by electrically attaching the second die to the first die though the flip chip attachment. In some embodiments, this is accomplished by electrically connecting through the flip chip attachment at least one of the plurality of bumps on the frontside of the second die to the at least one of the plurality of pads on the backside of the first die such that the frontside of the second die is electrically coupled to the conductive surface of the substrate through the redistribution traces on at least one of the sides of the first die.

The next action 640 can include electrically coupling the third die to the substrate by electrically attaching the third die to the second die through the flip chip attachment. In some embodiments, this optional action is accomplished by electrically connecting through the flip chip attachment at least one of the plurality of bumps on the frontside of the third die to the at least one of the plurality of pads on the backside of the second die such that the frontside of the third die is electrically coupled to the conductive surface of the substrate through the redistribution traces on at least one of the sides of the first and second dies. One skilled in the art can envision that any number of dies can be stacked and electrically attached to each other through flip chip attachment. The invention is not limited to only three dies as shown in the stacked flip chip assembly 100 in FIG. 1.

In some embodiments, the electrically connecting through flip chip attachment further includes applying solder flux on the plurality of contact pads of the substrate, and the backsides of the first and second dies, and placing the frontsides of the first, second, and third dies over the substrate, and the backsides of the first and second dies, respectively. Further the process can include aligning the plurality of contact bumps on the frontsides of the first, second and third dies over the plurality of contact pads on the substrate, first and second dies, respectively. Next, the process includes reflowing the solder to electronically connect the plurality of contact bumps with the plurality of contact pads.

In some embodiments, electrically connecting through the flip chip attachment further includes disposing anisotropic conductive film between the frontsides of the first, second, and third dies and the plurality of contact pads on the substrate, and backsides of the first and second dies, respectively. Then the process further includes applying heat and pressure to harden and adhere the anisotropic conductive film to provide the electrical connection between frontsides of the first, second, and third dies and the plurality of contact pads on the substrate, and backsides of the first and second dies, respectively.

In some embodiments, the first, second, and third dies are integrated circuit devices such as microprocessors, logic devices, memories, or any other application specific integrated circuit devices.

The above described method and apparatus provides, among other things, a stacked flip chip assembly that substantially enhances integrated circuit density and reliability in a multi chip module.

It is to be understood that the above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

What is claimed is:

1. A stacked flip chip assembly, comprising:
a first die having front and backsides, wherein the backside is disposed across from the frontside, wherein the backside is electrically connected to the frontside; and
a second die having front and backsides, wherein the backside is disposed across from the frontside, wherein the backside is electrically connected to the front side, wherein the second die is disposed on the backside of the first die such that the frontside of the second die is facing the backside of the first die, and further the frontside of the second die is electrically connected through the flip chip attachment to the backside of the first die.

2. The assembly of claim 1, wherein the front and back sides of the second die are electrically connected.

3. The assembly of claim 2, further comprising:
a third die having front and backsides, wherein the frontside is disposed across from the backside, wherein the backside of the second die is electrically connected to the frontside of the second die,
wherein the third die is disposed on the backside of the second die such that the frontside of the third die is facing the backside of the second die, wherein the frontside of the third die is electrically connected through the flip chip attachment to the backside of the second die.

4. The assembly of claim 3, wherein the front and back sides of the third die are electrically connected.

5. A assembly of claim 4, further comprising:
a substrate having a conductive surface, wherein the frontside of the first die is electrically connected through a flip chip attachment to the conductive surface of the substrate, wherein the frontside of the second die is further electrically connected to the substrate through the first die, and wherein the frontside of the third die is further electrically connected to the substrate through the first and second dies.

6. The assembly of claim 5, wherein the front and backsides of the first, second, and third dies have a plurality of conductive bumps, and a plurality of conductive pads such that the plurality of conductive pads and the plurality of conductive bumps on the first and second dies are disposed to match with the plurality of conductive bumps and the plurality of conductive pads on the frontsides of the second and third dies when the second die is disposed on the first die and further the third die is disposed on the second die.

7. The assembly of claim 6, wherein the plurality of conductive bumps are selected from the group consisting of solder balls, solder bumps, solder protrusions, controlled collapse chip connects, and conductive protrusions that facilitate in providing an electrical connection with the plurality of contact pads.

8. The assembly of claim 7, wherein the conductive surface of the substrate has a plurality of conductive pads to electrically connect the frontsides of the first, second, and third dies to the substrate when the plurality of conductive pads are electrically connected to the plurality of conductive bumps on the first die.

9. The assembly of claim 8, wherein the front and backsides of the first die are electrically connected by having a plurality of conductive layers on the front and backsides of the first die, and further having a plurality of redistribution traces formed along at least one side of the first die to electrically connect the conductive layers on the front and backsides of the first die.

10. The assembly of claim 9, wherein the front and backsides of the second die are electrically connected through a plurality of conductive layers on the front and backsides of the second die, and further having conductive redistribution traces formed along at least on one of the sides of the second die to electrically connect the conductive layers on the front and backsides of the second die.

11. The assembly of claim 10, wherein the first, second, and third dies are integrated circuit devices, wherein the integrated circuit devices are selected from the group consisting of microprocessors, logic devices, memories, and any other application specific integrated circuit devices.

12. The assembly of claim 11, wherein the plurality of conductive redistribution traces are electrically conductive side traces electrically connecting at least one of the plurality of contact pads on the frontsides with at least one of the plurality of conductive bumps on the backsides of the first and second dies, respectively.

13. The assembly of claim 11, wherein the plurality of conductive bumps on the second die are electrically connected to at least one of the plurality of conductive pads on the first die using an electrically conductive epoxy.

14. The assembly of claim 11, wherein the front and backsides of the first, second, and third dies have integrated circuit layers.

15. The assembly of claim 13, wherein the first, second, and third dies are formed from semiconductor substrates selected from the group consisting of silicon, gallium arsenide, silicon on insulator, and any other such materials suitable for supporting integrated circuit layers.

16. The assembly of claim 11 further comprising:
encapsulant over and around the substrate, first, second and third dies, wherein the encapsulant is selected from the group consisting of an overmold, an under fill, or any other such filling materials that assist in mechanically holding the stacked flip chip assembly.

17. A semiconductor die, comprising:
front and back sides, wherein the front and back sides comprising a plurality of conductive layers, and further the die having a plurality of redistribution traces formed along at least one side of the first die to electrically connect the conductive layers on the front and backsides of the die.

18. The die of claim 17, wherein the front and backsides of the die has integrated circuit layers.

19. The die of claim 17, wherein the die is a integrated circuit device, wherein the integrated circuit device is selected from the group consisting of microprocessors, logic devices, memories, and any other application specific integrated circuit devices.

20. The die of claim 17, wherein the front and backsides of the die has a plurality of conductive bumps, and a plurality of conductive pads such that the plurality of conductive pads and the plurality of conductive bumps.

21. The die of claim 20, wherein the plurality of conductive redistribution traces are electrically conductive side traces electrically connecting at least one of the plurality of contact pads on the frontside with at least one of the plurality of conductive bumps on the backside of the die.

22. A method of packaging a stacked flip chip assembly, comprising:
electrically connecting through a flip chip attachment a first die to a second die such that the second die is disposed on the first die.

23. The method of claim 22, further comprising:
electrically connecting through the flip chip attachment a third die to the second die such that the third die is disposed on the second die and is across from the first die.

24. The method of claim 23, further comprising:
a substrate having a conductive surface, wherein the first die is electrically through the flip chip attachment to the conductive surface of the substrate such that the substrate is disposed across from the first, second and third dies, further the second and through third dies are electrically connected to the substrate through the first die.

25. The method of claim 24, wherein electrically connecting the second die to the substrate through the first die comprises:
electrically connecting the second die to the substrate through conductive redistribution traces disposed on at least one of the sides of the first die.

26. The method of claim 25, wherein electrically connecting the third die to the substrate through the first and second dies comprises:
electrically connecting the third die to the substrate through conductive redistribution traces disposed on at least one of the sides of the first and second dies.

27. The method of claim 26, wherein electrically connecting the through the flip chip attachment comprises disposing solder flux between the front and backsides and reflowing solder to electrically connect the front and back.

28. A method of fabricating a flip chip, comprising:
producing a semiconductor wafer;
producing first, and second dies having front and backsides by cutting the semiconductor wafer, wherein the front and backsides are disposed across from each other;
forming patterned conductive distribution layers on the front and backsides of the first and second dies;
adding a plurality of conductive bump interconnect materials and conductive pads to the frontsides of the first, and second dies;
adding the plurality of conductive bumps and conductive pads to the backsides of the first and second dies; and
forming a plurality of conductive redistribution traces on at least one of the sides of the first and second dies to electrically connect the formed conductive distribution layers on the front and backsides of the first and second dies by masking the front and backsides such that only the at least one of the sides of the first and second dies are exposed to form the conductive redistribution traces.

29. The method of claim 28, further comprising:
electrically connecting through flip chip attachment at least one of the plurality of bumps on the frontside of the first die with a plurality of conductive pads on a conductive side of a substrate; and
electrically connecting through flip chip attachment at least one of the plurality of bumps on the frontside of the second die to the at least one of the plurality of pads on the backside of the first die such that the frontside of the second die is electrically connected to the conductive surface of the substrate through the conductive redistribution traces on at least one of the sides of the first die.

30. The method of claim 29, further comprising:
producing a third die having front and backsides by cutting the silicon wafer, wherein the frontside is disposed across from the backside;
forming patterned conductive distribution layers on the front and backsides of the third die;
adding a plurality of conductive bump interconnect materials to frontside of the third die;
adding a plurality of conductive pads to the backside of the third die;
forming a plurality of conductive redistribution traces on the sides of the third die to electrically connect at least one of the formed conductive distribution layers on the front and backsides of the third die; and
electrically connecting through flip chip attachment at least one of the plurality of bumps on the frontside of the third die to at least one of the plurality of pads on the backside of the second die such that the frontside of the third die is electrically connected to the conductive surface of the substrate through the formed redistribution traces on the sides of the first and second dies.

31. The method of claim 30, wherein forming the patterned conductive distribution layers on the front and backsides of the first, second, and third dies further comprises:
depositing mechanically protective layers over the patterned conductive distribution layers;
depositing diffusion barrier layers over the mechanically protective layers;
depositing adhesion layers over the diffusion barrier layers;
depositing electrically conductive layers over the adhesion layers;
patterning the electrically conductive layers;
depositing protective layers over the patterned electrical layers;
patterning plurality of conductive bump materials;
patterning protective layers over the conductive bump materials; and
patterning diffusion layers over the protective layers.

32. The method of claim 31, wherein forming the plurality of conductive redistribution traces on the sides of the first, second, and third dies further comprises:
holding at least one of the first, second, and third dies in place using a specially designed positioning device such that the front and backsides of the at least one of the first, second, and third dies are masked;
depositing a mechanically protective layer over at least one of the sides of the first, second, and third dies;
patterning the mechanically protective layer;
depositing a diffusion barrier over the mechanically protective layer;
depositing an adhesive layer over the diffusion barrier;
depositing electrically conductive layers connecting the patterned conductive traces on the front and backsides of the first, second, and third dies;
patterning the electrically conductive layers;
depositing protective layers over the patterned electrically conductive layers;
patterning protective layers over the deposited protective layers; and
patterning diffusion layers over the protective layers.

33. The method of claim 32, wherein electrically connecting through flip chip attachment the frontside of the first die to the plurality of contact pads on the substrate further comprises:
applying solder flux on the plurality of contact pads on the substrate;
placing the frontside of the first die including the plurality of contact bumps facing the plurality of contact pads on the substrate;
aligning the plurality of contact bumps on the frontside of the first die with the plurality of contact pads on the substrate; and
reflowing solder to electrically connect the plurality of contact bumps on the first die with the plurality of contact pads on the substrate.

34. The method of claim 33, wherein electrically connecting through flip chip attachment the frontside of the second die to the plurality of contact pads on the backside of the first die further comprises:
applying solder flux on the plurality of contact pads on the backside of the first die;
placing the frontside of the second die including the plurality of contact bumps facing the plurality of contact pads on the backside of the first die;
aligning the plurality of contact bumps with the plurality of contact pads; and
reflowing solder to electrically connect the plurality of contact bumps on the frontside of the second die with the plurality of contact pads on the backside of the first die.

35. The method of claim 34, wherein electrically connecting through flip chip attachment the frontside of the third die to the plurality of contact pads on the backside of the second die further comprises:
applying solder flux on the plurality of contact pads on the backside of the second die;
placing the frontside of the third die including the plurality of contact bumps facing the plurality of contact pads on the backside of the second die;
aligning the plurality of contact bumps with the plurality of contact pads; and
reflowing solder to electrically connect the plurality of contact bumps on the frontside of the third die with the plurality of contact pads on the backside of the second die.

36. The method of claim 33, wherein the first, second, and third dies are integrated circuit devices, wherein the integrated circuit devices are selected from the group consisting of microprocessors, logic devices, memories, and any other application specific integrated circuit devices.

37. The method of claim 33, wherein the first, second, and third dies are formed from semiconductor substrates selected from the group consisting of a silicon, a gallium arsenide, a silicon on insulator, and any other such materials suitable for supporting integrated circuit layers.

38. The method of claim 33, wherein electrically connecting through flip chip attachment the frontside of the first die to the plurality of contact pads on the substrate, the backside of the first die to the frontside of the second die, the backside of the second die and the frontside of the third die further comprises:
disposing anisotropic conductive film between the frontside of the first die to the plurality of contact pads on the substrate, the backside of the first die to the frontside of the second die, the backside of the second die and the frontside of the third die; and
applying heat and pressure to harden and adhere the anisotropic conductive film, to provide electrical connection between the frontside of the first die to the plurality of contact pads on the substrate, the backside of the first die to the frontside of the second die, the backside of the second die and the frontside of the third die.
